(19) United States
(12) Patent Application Publication
(10) Pub. No.: US 2025/0334644 A1
(43) Pub. Date: Oct. 30, 2025

(54) SYSTEMS AND METHODS FOR FACILITATING BATTERY FAULT PREDICTION

(71) Applicant: Coulomb AI, Inc., San Francisco, CA (US)

(72) Inventors: Santanu MONDAL, Bangalore (IN); Khushboo SHRIVASTAVA, Bangalore (IN)

(21) Appl. No.: 19/195,194

(22) Filed: Apr. 30, 2025

Related U.S. Application Data
(60) Provisional application No. 63/640,714, filed on Apr. 30, 2024.

(51) Int. Cl. G01R 31/392; G01R 31/367; G01R 31/3842

(52) U.S. Cl. CPC G01R 31/392; G01R 31/367; G01R 31/3842; H01M 2220/20

(57) ABSTRACT

A system for facilitating battery fault prediction is configurable to: (i) access a set of raw data comprising battery sensor data associated with a physical battery and operation data associated with operation of the physical battery; (ii) obtain an estimated battery state for the physical battery by utilizing the battery sensor data as input to a battery digital twin; (iii) obtain a battery fault prediction by utilizing (a) the estimated battery state obtained via the battery digital twin and (b) operation input based on the operation data as input to a battery fault prediction model, and wherein the battery fault prediction comprises one or more likelihood metrics indicating a likelihood of one or more battery faults occurring within one or more predetermined time periods; and (iv) cause presentation of an alert via a battery fault notification system.

### CROSS-REFERENCE TO RELATED APPLICATIONS

This application claims priority to and the benefit of U.S. Provisional Patent Application No. 63/640,714, filed on Apr. 30, 2024, and entitled “SYSTEMS AND METHODS FOR FACILITATING BATTERY FAULT PREDICTION”, the entirety of which is incorporated herein by reference for all purposes.

### BACKGROUND

Batteries are a cornerstone of modern technology and have found their way into an extensive array of devices, ranging from small-scale devices (e.g., smartphones and laptops) to larger and more demanding devices such as electric vehicles (EVs) and renewable energy storage systems. In small devices, batteries are primarily used for their portability and ability to store significant energy in a compact form. This enables these devices to operate for extended periods without being tethered to a power source. In the realm of electric vehicles, batteries are not just a power source but a fundamental component that defines the vehicle's range, performance, and overall efficiency. These high-capacity batteries are designed to handle larger power demands and endure the rigors of automotive use, including varying load demands, extensive recharge cycles, and physical disturbances associated with roadway travel.

However, the widespread reliance on batteries also brings with it a range of challenges, particularly when faults occur. Battery faults can range from simple degradation over time, which reduces capacity and efficiency, to more serious issues like internal short circuits, thermal runaway, or electrolyte leakage. These faults can drastically affect the performance and safety of the device or vehicle. In the case of smartphones or laptops, a faulty battery might mean reduced usage time or, in extreme cases, a risk of overheating or fire. For electric vehicles, the stakes are higher. A battery fault can mean a significantly reduced range, compromised performance, or, in worst-case scenarios, risks to passenger safety due to fire or explosions.

The subject matter claimed herein is not limited to embodiments that solve any disadvantages or that operate only in environments such as those described above. Rather, this background is only provided to illustrate one exemplary technology area where some embodiments described herein may be practiced.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings in which:

FIG. 1 illustrates example components of an example system that may include or be used to implement one or more disclosed embodiments.

FIG. 2A illustrates a conceptual representation of acquisition of raw data associated with a battery and its operational environment, in accordance with implementations of the disclosed subject matter.

FIG. 2B illustrates a conceptual representation of utilizing the raw data of FIG. 2A to determine (i) operation input and (ii) an estimated battery state via a battery digital twin, in accordance with implementations of the disclosed subject matter.

FIG. 2C illustrates a conceptual representation of determining a fault prediction by utilizing the estimated battery state and the operation input as input to a battery fault prediction model, in accordance with implementations of the disclosed subject matter.

FIG. 2D illustrates a conceptual representation of presenting an alert or refraining from presenting an alert based on characteristics of the fault prediction, in accordance with implementations of the disclosed subject matter.

FIG. 3 illustrates a conceptual representation of training a battery fault prediction model, in accordance with implementations of the disclosed subject matter.

FIGS. 4 and 5 illustrate example flow diagrams depicting acts associated with facilitating battery fault prediction, in accordance with implementations of the disclosed subject matter.

### DETAILED DESCRIPTION

Disclosed embodiments are generally directed to systems, methods, apparatuses, and techniques for facilitating battery fault prediction.

As noted above, widespread reliance on batteries is associated with a range of challenges, particularly when faults occur. Battery faults can result in performance degradation, total battery failure/inoperability, or even safety risks such as fire or explosions.

Existing systems in many devices, especially in EVs, incorporate several reactive measures to address battery faults. These measures are typically part of a battery management system (BMS), which monitors various parameters like temperature, voltage, and current. When abnormal values are detected, indicating a fault, the BMS can take reactive actions. For instance, if the system detects an overheating cell, it may temporarily reduce power output to mitigate the risk, or in more severe cases, it might shut down the battery entirely to prevent damage or a safety hazard.

However, such reactive systems have their limitations. They are often only triggered when a fault has already started to manifest, which can sometimes be too late to prevent damage or safety risks.

Disclosed embodiments are directed to proactive battery fault detection systems, methods, and techniques that can predict the likelihood of battery faults before they occur, enabling corrective or preventive action to be taken prior to battery fault occurrences. Implementation of the disclosed subject matter can improve battery performance by providing predictive warnings or alerts about prospective battery failures/faults. The predictive warnings or alerts generated and presented in accordance with the disclosed techniques can indicate the type of fault that is likely to occur, as well as the time period within which the fault is likely to occur (e.g., within 2 days, within 7 days, or any other time period). In some instances, alerts can include proposed or recommended operating strategies that can mitigate the risk of fault or further battery degradation. Such alerts can enable users to take corrective or avoidance actions, which can mitigate inconvenience and/or safety risks to users of battery-powered devices and can increase battery life, battery health, and/or performance.

As will be described in more detail hereinafter, battery fault prediction output can be provided via a battery fault prediction model, which can comprise a single predictive machine learning model or an ensemble of multiple models (e.g., artificial neural networks, deep neural networks, etc.). A battery fault prediction model may be trained using raw data, derived metrics/indicators or operation input, and/or estimated battery internal state variables. The raw data can be collected via sensors associated with physical batteries or devices in which the physical batteries are implemented (e.g., electric vehicle sensor systems, mobile device sensor systems, energy storage systems, etc.). The raw data may be collected for batteries in various contexts, such as idle batteries or batteries in live operation. The raw data collected via the sensors can be transmitted to a cloud system and/or an on-premises system, which can enable more powerful computing and/or storage of data than the devices in which the physical batteries are implemented.

The operation input usable to train the battery fault prediction model can be derived from the raw data (e.g., by deriving features from the raw data), or may include raw data itself. The raw data can also be used to optimize battery digital twins for each physical battery for which raw data is collected. The battery digital twins may simulate a corresponding physical battery and can estimate the battery internal state variables usable to train the battery fault prediction model.

Battery fault data, or a dataset of battery faults, may serve as ground truth output for training the battery fault prediction model. The battery fault data may be obtained by curating target values from battery faults detected in real-world batteries and/or from inferred battery faults from the raw data and/or estimated battery internal state variables.

A validation dataset for evaluating performance of a trained battery fault prediction model may also comprise estimated battery internal state variables/data, operation input, and battery fault data. If a trained battery fault prediction model satisfies one or more performance metrics (e.g., prediction error that is below a threshold), the trained battery fault prediction model may be deployed for use in conjunction with one or more real-world batteries to facilitate proactive fault prediction therefor.

Implementing the disclosed principles can enable improved preventive maintenance for battery systems, which can save operating costs and/or greatly improve the safety of assets and/or personnel.

Although the examples discussed herein focus, in at least some respects, on batteries implemented in electric vehicles, one will appreciate, in view of the present disclosure, that the disclosed principles may be applied to any type of battery in any use environment (e.g., idle or stored batteries, batteries used in energy storage applications, batteries used in solar or other power generation systems, home and business backup power, mobile electronic devices, and/or others).

### Example Systems and Components

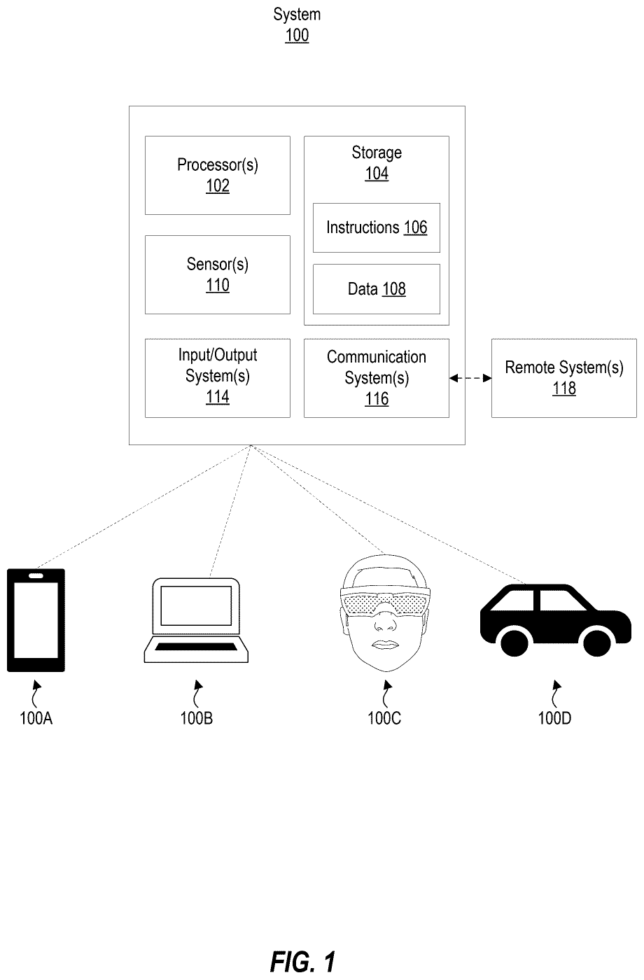

FIG. 1 illustrates various example components of a system 100 that may be used to implement one or more disclosed embodiments. For example, FIG. 1 illustrates that a system 100 may include processor(s) 102, storage 104, sensor(s) 110, input/output system(s) 114 (I/O system(s) 114), and communication system(s) 116. Although FIG. 1 illustrates a system 100 as including particular components, one will appreciate, in view of the present disclosure, that a system 100 may comprise any number of additional or alternative components.

The processor(s) 102 may comprise one or more sets of electronic circuitry that include any number of logic units, registers, and/or control units to facilitate the execution of computer-readable instructions (e.g., instructions that form a computer program). Such computer-readable instructions may be stored within storage 104. The storage 104 may comprise physical system memory and may be volatile, non-volatile, or some combination thereof. Furthermore, storage 104 may comprise local storage, remote storage (e.g., accessible via communication system(s) 116 or otherwise), or some combination thereof. Additional details related to processors (e.g., processor(s) 102) and computer storage media (e.g., storage 104) will be provided hereinafter.

In some implementations, the processor(s) 102 may comprise or be configurable to execute any combination of software and/or hardware components that are operable to facilitate processing using machine learning models or other artificial intelligence-based structures/architectures. For example, processor(s) 102 may comprise and/or utilize hardware components or computer-executable instructions operable to carry out function blocks and/or processing layers configured in the form of, by way of non-limiting example, single-layer neural networks, feed forward neural networks, radial basis function networks, deep feed-forward networks, recurrent neural networks, long-short term memory (LSTM) networks, gated recurrent units, autoencoder neural networks, variational autoencoders, denoising autoencoders, sparse autoencoders, Markov chains, Hopfield neural networks, Boltzmann machine networks, restricted Boltzmann machine networks, deep belief networks, deep convolutional networks (or convolutional neural networks), deconvolutional neural networks, deep convolutional inverse graphics networks, generative adversarial networks, liquid state machines, extreme learning machines, echo state networks, deep residual networks, Kohonen networks, support vector machines, neural Turing machines, and/or others.

As will be described in more detail, the processor(s) 102 may be configured to execute instructions 106 stored within storage 104 to perform certain actions. The actions may rely at least in part on data 108 stored on storage 104 in a volatile or non-volatile manner.

In some instances, the actions may rely at least in part on communication system(s) 116 for receiving data from remote system(s) 118, which may include, for example, separate systems or computing devices, sensors, and/or others. The communications system(s) 116 may comprise any combination of software or hardware components that are operable to facilitate communication between on-system components/devices and/or with off-system components/devices. For example, the communications system(s) 116 may comprise ports, buses, or other physical connection apparatuses for communicating with other devices/components. Additionally, or alternatively, the communications system(s) 116 may comprise systems/components operable to communicate wirelessly with external systems and/or devices through any suitable communication channel(s), such as, by way of non-limiting example, Bluetooth, ultra-wideband, WLAN, infrared communication, and/or others.

FIG. 1 illustrates that a system 100 may comprise or be in communication with sensor(s) 110. Sensor(s) 110 may comprise any device for capturing or measuring data representative of perceivable or detectable phenomenon. By way of non-limiting example, the sensor(s) 110 may comprise one or more image sensors, electrical sensors, location/positioning sensors, microphones, thermal sensors, barometers, magnetometers, accelerometers, gyroscopes, and/or others.

Furthermore, FIG. 1 illustrates that a system 100 may comprise or be in communication with I/O system(s) 114. I/O system(s) 114 may include any type of input or output device such as, by way of non-limiting example, a touch screen, a mouse, a keyboard, a controller, and/or others, without limitation. For example, the I/O system(s) 114 may include a display system that may comprise any number of display panels, optics, laser scanning display assemblies, and/or other components.

FIG. 1 conceptually represents that the components of the system 100 may comprise or utilize various types of devices, such as mobile electronic device 100A (e.g., a smartphone), personal computing device 100B (e.g., a laptop), a mixed-reality head-mounted display 100C (HMD 100C), a vehicle 100D (e.g., a drone), and/or other devices. A system 100 may take on other forms in accordance with the present disclosure.

### Battery Fault Prediction

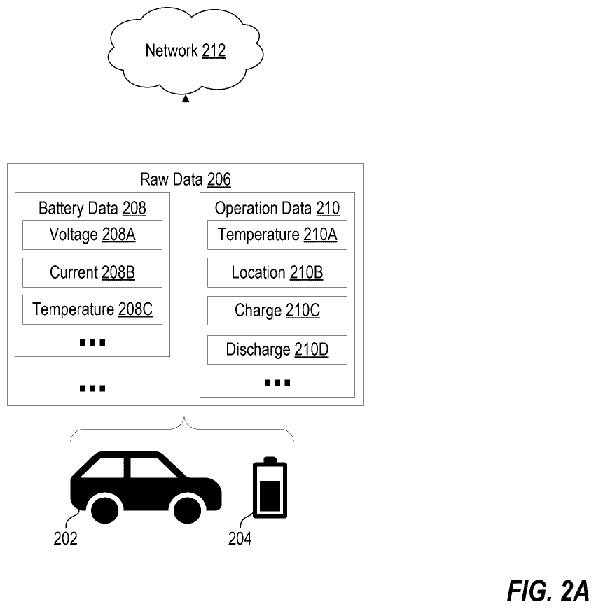

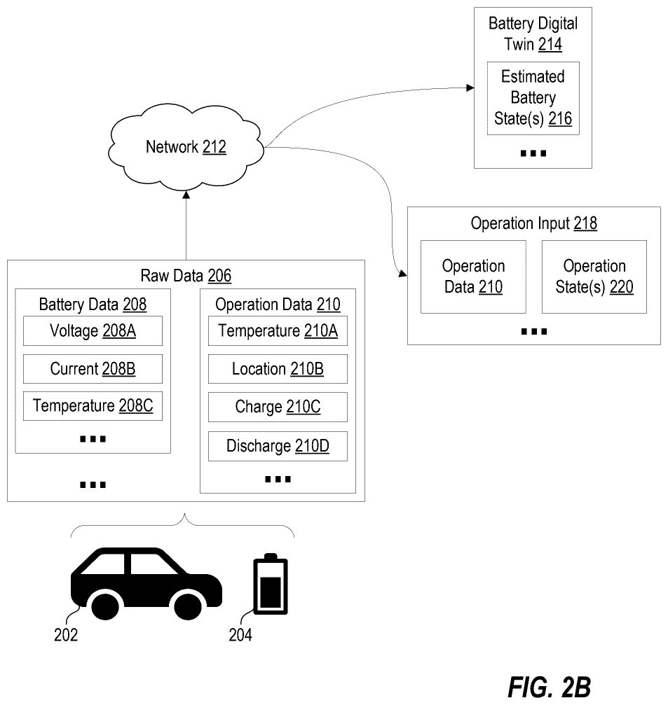

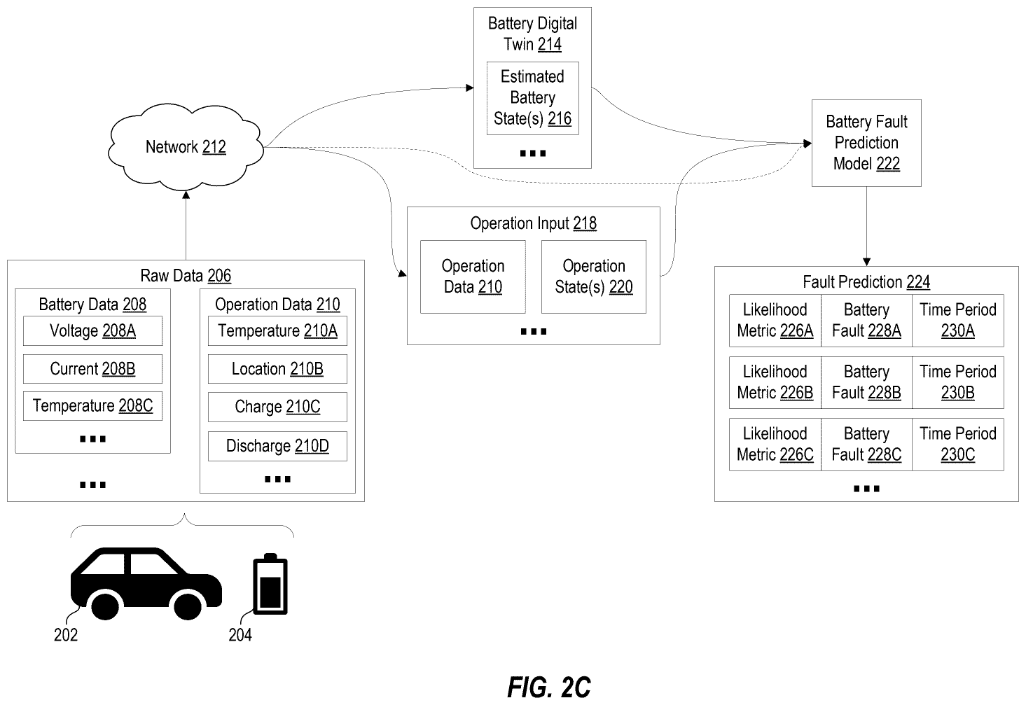

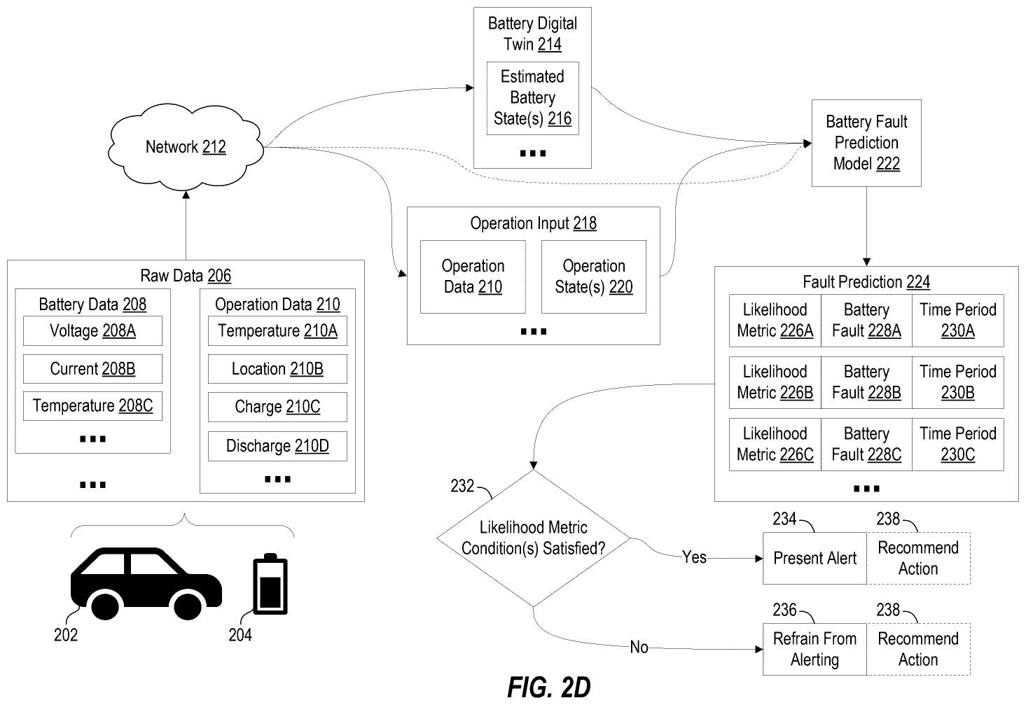

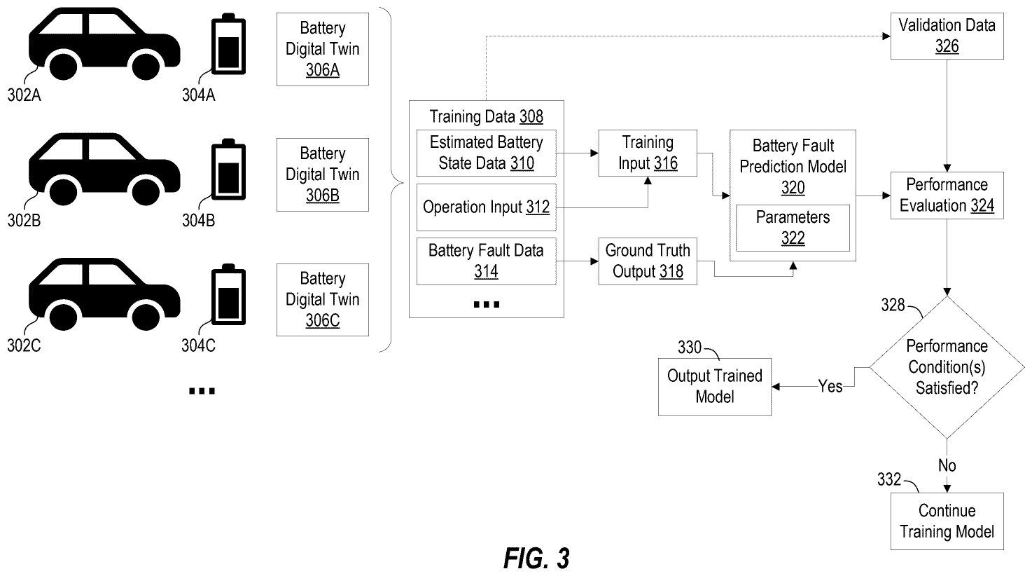

FIGS. 2A, 2B, 2C, 2D, and 3 illustrate various components, data objects, and processes associated with facilitating battery fault prediction. The elements shown and described with reference to FIGS. 2A, 2B, 2C, 2D, and 3 can correspond to or be performed via components of FIG. 1 (e.g., using processor(s) 102, storage 104, sensor(s) 110, etc.).

FIG. 2A illustrates a conceptual representation of acquisition of raw data 206 associated with a physical battery 204 and its operational environment. In the example of FIG. 2A the operational environment for the physical battery 204 comprises use in conjunction with an electric vehicle 202. As noted above, the electric vehicle use case is utilized by way of example and illustration only, and is not limiting of the principles described herein.

In the example of FIG. 2A, the raw data 206 includes battery data 208 and operation data 210. The ellipsis within the depiction of the raw data 206 in FIG. 2A indicates that the raw data 206 can include additional or alternative metrics than those specifically shown in FIG. 2B.

The battery data 208 is associated with the physical battery 204, and the operation data 210 is associated with operation of the physical battery 204 within its operational environment (e.g., in conjunction with the electric vehicle 202). As shown in FIG. 2A, the battery data 208 may include various types of data, such as voltage data 208A, current data 208B, and temperature data 208C for one or more components of the physical battery 204. The battery data 208 may be acquired by one or more sensors associated with the components of the physical battery 204. For example, the physical battery 204 may include voltage sensors, current sensors, and/or temperature sensors associated with the entire physical battery 204, individual packs of the physical battery 204, individual cells of the packs, etc. The ellipsis within the depiction of the battery data 208 in FIG. 2A indicates that the battery data 208 can comprise additional or alternative types of data. The battery data 208 may be temporally indexed to capture temporal variance and/or trends among the battery data 208.

The operation data 210 of the example of FIG. 2A may include various types of data associated with the use/operation and/or operational environment of the physical battery 204. For instance, the operation data 210 may comprise environment components such as environment temperature data 210A, location data 210B (e.g., altitude, global position), terrain data, and/or time data (e.g., time of day, date, season, etc.). The operation data 210 may additionally (or alternatively) include use components such as charge operation data 210C, discharge operation data 210D, and/or other types of data such as speed data, acceleration data, motor rpm data, and/or other data associated with components used in conjunction with the physical battery 204 (as indicated by the ellipsis within the depiction of the operation data 210 in FIG. 2A). The operation data 210 may be captured via sensors within the use environment of the physical battery 204 and/or may be acquired via other sources (e.g., accessing data repositories for weather/temperature information, terrain information, etc.). For instance, in the example of FIG. 2A, various sensors for capturing the operation data 210 may be part of the electric vehicle 202. For example, one or more temperature sensors of the electric vehicle 202 may capture temperature data inside or outside of the electric vehicle 202 or proximate to the physical battery 204 to provide the environment temperature data 210A. As another example, one or more global positioning systems or inertial tracking systems (e.g., inertial measurement units) of the electric vehicle 202 may provide the location data 210B, which may comprise position/location data, distance traveled, speed, acceleration, etc. As yet another example, the charge operation data 210C and/or the discharge operation data 210D may be captured by various sensors of the electric vehicle 202 to provide information related to the conditions associated with charging or discharging of the physical battery 204 of the electric vehicle 202. For instance, the charge operation data 210C may comprise ambient temperature data captured while charging the physical battery 204, the type of charger used or rate of charge, controls/operations of the electric vehicle 202 that are activated/triggered to cause charging of the physical battery 204 (e.g., regenerative braking). The discharge operation data 210D may similarly comprise ambient temperature data and/or other components such as controls/operations of the electric vehicle 202 that are activated/triggered to cause discharge of the physical battery 204 (e.g., propulsion, regenerative braking, air condition and heating, information/entertainment systems, lighting, power steering and brakes, windshield wipers/defrosters, onboard computers and sensors, auxiliary features, vehicle-to-grid systems, battery heating/cooling, etc.).

FIG. 2A depicts the raw data 206 being transferred over a network 212, which may enable the raw data 206 to be stored and/or accessed via cloud infrastructure. For instance, the electric vehicle 202 may transmit the raw data 206 acquired via various sensors of the electric vehicle 202 and/or the physical battery 204 to cloud infrastructure via a subscriber identity module (SIM) card or other IoT method. Various systems may thus access the raw data 206 to perform various operations therewith, such as generating battery fault prediction output as shown and described with reference to FIGS. 2B, 2C, and 2D (or training a model to do the same, as shown and described with reference to FIG. 3). Although the examples provided with reference to FIGS. 2B, 2C, and 2D may focus, in at least some respects, on accessing raw data 206 via cloud infrastructure to perform operations therewith, one will appreciate, in view of the present disclosure, that the raw data 206 may be accessed by on-premises systems/components to perform such operations.

In one example, the battery data 208 comprises real-time battery sensor data (e.g., voltage, current, and temperature) captured using a telematics unit associated with the battery 204, which may transmit the real-time battery sensor data to a centralized cloud analytics engine (e.g., via network 212, where the cloud analytics engine may comprise or communicate with the battery digital twin 214 and/or the battery fault prediction model 222). The telematics engine may transmit and/or acquire the real-time battery sensor data to the centralized clout analytics engine at any desired sampling frequency, such as 0.1 Hz. The operational context may be enriched by also transmitting operation data 210, such as GPS telemetry and/or ambient environmental data (e.g., outside temperature, altitude, trip profile).

FIG. 2B illustrates a conceptual representation of utilizing the raw data 206 as input to a battery digital twin 214. For example, a system may access the raw data 206 via cloud infrastructure over the network 212 and utilize at least part of the raw data 206 (e.g., the battery data 208) as input to the battery digital twin 214. In the example of FIG. 2B, the battery digital twin 214 is associated with the physical battery 204 and mimics the behavior or characteristics of the physical battery 204. In this regard, the battery digital twin 214 of FIG. 2B can be configured to generate estimated battery state(s) 216 for the physical battery 204 by processing the battery data 208 captured for the physical battery 204.

The estimated battery state(s) 216 may comprise one or more estimations of internal state variables for the physical battery 204 based on the battery data 208. By way of non-limiting example, the estimated battery state(s) 216 may comprise one or more estimations of capacity, state of charge, state of health, state of power, voltage state, current state, temperature state, internal resistance (e.g., including interfacial resistance), charge transfer resistance (e.g., electrode state, which may indicate electrode deposits), electrolyte state (e.g., electrolyte conductivity), charge/discharge cycles, depth of discharge, cell balance, pack balance, charge characteristics (e.g., charging efficiency; charge rate; voltage response; temperature effects; rates of change or peaks in temperature, voltage, and/or current during charging, etc.), or discharge characteristics (e.g., discharge rate; voltage response; temperature effects; rate of self-discharge; rates of change or peaks in temperature, voltage, and/or current during discharging).

The battery digital twin 214 may comprise one or more battery simulation models configured to provide estimated battery state output in response to battery sensor data input. The battery simulation models may include one or more (or a combination of) equivalent circuit models (e.g., Thevenin model, Norton model, etc.), electrochemical models (e.g., Newman-Tiedemann model, single particle model, Butler-Volmer equation, etc.), battery management system models (e.g., state of charge estimation model, Kalman filter, recursive least squares method, state of health prediction model, cycle counting, capacity fade modeling, etc.), thermal models (e.g., thermal equivalent circuit model, computational fluid dynamics model, etc.), aging models (e.g., calendar aging model, cycling aging model), physics-based models (e.g., pseudo two-dimensional (P2D) model, finite element method (FEM) model, multi-physics models, etc.), machine learning models, and/or others.

The estimated battery state(s) 216 generated by the battery digital twin 214 in association with the physical battery 204 may be continuously updated over time in response to updated battery data 208 captured in association with the physical battery 204. In some implementations, sequentially determined estimated battery state(s) 216 temporally indexed to capture variance and/or trends for the internal state of the physical battery 204. In some instances, the battery digital twin 214 can be configured to estimate battery states for future timepoints.

In some implementations, in addition to generating estimated battery state(s) 216, a battery digital twin 214 can be used to generate other outputs or to determine other information, as indicated in FIG. 2B by the ellipsis within the depiction of the battery digital twin 214. In some instances, in addition to facilitating generation of estimated battery state(s) 216 via the battery digital twin 214, the battery data 208 can be used to update, tune, or calibrate the battery digital twin 214 itself. For example, a system may utilize up-to-date voltage data 208A, current data 208B, and/or temperature data 208C associated with the physical battery 204 to tune boundary conditions of the battery digital twin 214 or otherwise calibrate the battery digital twin 214. Such functionality can maintain the ability of the battery digital twin 214 to mimic the current state of the physical battery 204 and/or estimate or predict future states of the physical battery 204.

FIG. 2B furthermore illustrates operation input 218, which may include the operation data 210 (as indicated in FIG. 2B by the presence of the operation data 210 within the depiction of the operation input 218) or be generated based on the operation data 210. For instance, FIG. 2B illustrates that the operation input 218 can include operation state(s) 220, which may be generated based on the operation data 210. In some instances, the operation state(s) 220 may comprise features derived from the operation data 210 via one or more machine learning or deep learning models (e.g., convolutional neural networks (CNNs), recurrent neural networks (RNNs), long short-term memory (LSTM) models, gated recurrent unit (GRU) models, autoencoders, transformers, random forests, gradient boosting machines, deep belief networks (DBNs), graph neural networks (GNNs), and/or others). The operation state(s) 220 may be temporally indexed to capture variance and/or trends, or for association with temporally corresponding estimated battery state(s) 216 and/or the battery data 208. In some implementations, the operation state(s) 220 may be estimated or predicted for future timepoints.

The battery digital twin associated with a given battery 204 may be updated at any desirable time interval (e.g., every 15 days), and may be configured to produce estimations of internal state variables such as state of health (SoH), state of charge (SoC), internal resistance, thermal state, cell balancing efficiency, and/or others. Such estimations, along with time-aligned environmental and/or usage features, may form input for a trained machine-learning based fault prediction model hosted in the cloud (e.g., the battery fault prediction model 222).

As noted hereinabove, the operation input 218 and the estimated battery state(s) 216 may be utilized to determine battery fault predictions via a battery fault prediction model. FIG. 2C illustrates a conceptual representation of determining a fault prediction 224 by utilizing the estimated battery state(s) 216 and the operation input 218 as input to a battery fault prediction model 222. In some instances, the battery fault prediction model 222 utilizes one or more aspects of the raw data 206 to generate the fault prediction 224 output (as indicated in FIG. 2C by the dashed arrow extending from the network 212 toward the battery fault prediction model 222). The battery fault prediction model 222 may comprise one or more machine learning models configured to generate battery fault prediction output in response to estimated battery state and operation input. By way of non-limiting example, a battery fault prediction model 222 may comprise one or more (or a combination of) RNNs, hidden Markov models (HMMs), survival analysis models, cox proportional hazards models, machine learning ensemble methods, vector autoregression (VAR) methods, Bayesian structural time series (BSTS), Gaussian processes, temporal convolutional networks (TCNs), LSTMs, attention and/or transformer networks, neural basis expansion analysis, support vector machines for regression, GNNs, echo state networks, and/or others. Additional details related to training the battery fault prediction model 222 will be described hereinafter with reference to FIG. 3. In one example, the battery fault prediction model 222 is implemented as a hybrid ensemble of LSTM and gradient boosting classifiers, which may provided fault likelihood metrics (e.g., likelihood metrics 226A, 226B, 226C) for various failure modes (e.g., battery faults 228A, 228B, 228C), such as thermal runaway, inter-cell imbalance, progressive capacity degradation, and/or others.

The fault prediction 224 output by the battery fault prediction model 222 may include various components. For instance, FIG. 2C illustrates an example in which the fault prediction 224 includes likelihood metrics 226A, 226B, and 226C. Each of the likelihood metrics 226A, 226B, and 226C indicates the likelihood that a respective type of battery fault 228A, 228B, and 228C will occur within a respective time period 230A, 230B, and 230C for the physical battery 204. The likelihood metrics 226A, 226B, and 226C may comprise numerical likelihood scores (e.g., obtained via regression methods). The types of battery faults 228A, 228B, and 228C may include, by way of non-limiting example, thermal runaway (which can result in fire or explosion), rapid discharge, internal short circuit, cell imbalance, pack imbalance, rapid degradation, battery failure (e.g., inability to charge or discharge), battery underperformance (e.g., range reduction, loss of power/acceleration), and/or others. The time periods 230A, 230B, and 230C can be varied for different types of battery faults. In one illustrative, non-limiting example, a time period of 2 days may be utilized for determining a likelihood metric for thermal runaway battery faults, whereas a time period of 7 days may be utilized for determining a likelihood metric for cell imbalances or battery failures. Other time periods are within the scope of the present disclosure (e.g., hours, days, or weeks).

Although FIG. 2C provides an example in which the fault prediction 224 includes three likelihood metrics 226A, 226B, and 226C calculated for three types of battery fault 228A, 228B, and 228C for three time periods 230A, 230B, and 230C, a fault prediction 224 can comprise any quantity of likelihood metrics, types of battery faults, and time periods (as indicated in FIG. 2C by the ellipsis within the depiction of the fault prediction 224). For example, a fault prediction 224 can include multiple likelihood metrics determined for the same type of battery fault occurring within different time periods, and/or a fault prediction 224 can include multiple likelihood metrics determined for different types of battery faults occurring within the same time period. A fault prediction 224 can include any combination of likelihood metrics for one or more types of battery faults for one or more time periods, in accordance with the principles disclosed herein.

The fault prediction 224 can be used as a basis to determine whether to trigger an alert or notification related to the physical battery 204 experiencing a battery fault. For example, FIG. 2D conceptually illustrates determining whether the likelihood metrics 226A, 226B, and 226C of the fault prediction 224 satisfy one or more conditions (via decision block 232). In some implementations, the condition(s) include the likelihood metrics 226A, 226B, and 226C falling within or outside of one or more predetermined likelihood score ranges (or target ranges). The likelihood metrics associated with different types of battery faults and/or time periods may be tested against different likelihood score ranges to determine whether to cause presentation of an alert.

As shown in FIG. 2D, when a likelihood metric associated with a particular battery fault satisfies the condition(s) (indicated by the “Yes” extending from decision block 232), a fault notification system may present an alert (indicated by action block 234) indicating that the particular battery fault may occur within a time period associated with the likelihood metric. The alert may indicate the type of fault likely to occur and the amount of time within which the fault is likely to occur. For example, where a likelihood metric 226A for a battery fault 228A of thermal runaway occurring within a time period 230A of 2 days is sufficiently high (as determined at decision block 232), a fault notification system may cause presentation of an alert that indicates that an event associated with thermal runaway (e.g., fire, combustion) is likely to occur within 2 days (indicated by action block 234). Conversely, where the likelihood metric 226A for the battery fault 228A of thermal runaway occurring within the time period 230A of 2 days is sufficiently low (as determined at decision block 232), the fault notification system may refrain from presenting an alert (indicated by action block 236).

An alert notification system may take on various forms, such as a user interface proximate to the physical battery 204 (e.g., a user interface of the electric vehicle 202), an email system, a short messaging service (SMS) system, a software application (e.g., a smartphone or mobile electronic device application, or an enterprise-specific application such as a fleet management application), and/or others. In some implementations, the alert notification system is configured to present recommended actions (indicated in FIG. 2D by action blocks 238). In some instances, such recommended actions are based on the estimated battery state(s) 216 (or a detected trend/trajectory of estimated battery state) and can be presented whether or not the tested likelihood metrics indicate that a battery fault is likely within the applicable time period for the physical battery 204. By way of example, when a battery fault is likely, the recommended actions may take the form of activities that assist users in avoiding the battery fault or mitigating consequences of the battery fault. As another example, when a battery fault is not determined to be likely, the recommended actions may take the form of activities that can promote or prolong battery health. By way of illustration, and not limitation, recommended actions may include controlling or changing charge or discharge environments (e.g., charging/discharging patterns, hardware, rates, temperatures, etc.), controlling storage environments (e.g., temperature), implementing battery rest periods, initiating maintenance activities, and/or others.

FIG. 3 illustrates a conceptual representation of training a battery fault prediction model. In particular, FIG. 3 illustrates multiple physical batteries 304A, 304B, and 304C associated with respective devices 302A, 302B, 302C and battery digital twins 306A, 306B, and 306C. Information from the multiple physical batteries 304A, 304B, 304C, the devices 302A, 302B, 302C, and/or the battery digital twins 306A, 306B, 306C may be utilized to construct a set of training data 308 (any quantity of physical batteries, devices, and/or battery digital twins may be used to obtain training data, as indicated by the ellipsis below the physical batteries in FIG. 3). The battery digital twins 306A, 306B, and 306C may conceptually correspond to the battery digital twin 214 described hereinabove.

In the example of FIG. 3, the set of training data 308 includes estimated battery state data 310, operation input 312, and battery fault data 314 (and potentially other elements, as indicated by the ellipsis within the depiction of the set of training data 308 in FIG. 3). The estimated battery state data 310 may include multiple instances that conceptually correspond to the estimated battery state(s) 216 described hereinabove. For instance, the estimated battery state data 310 may include output of the battery digital twins 306A, 306B, 306C, etc. generated responsive to battery sensor data input associated with the respective physical batteries 304A, 304B, 304C, etc. The operation input 312 may include multiple instances that conceptually correspond to the operation input 218 described hereinabove. For instance, the operation input 312 may include or be based on operation data associated with operation of the various physical batteries 304A, 304B, 304C, etc.

The battery fault data 314 may include data indicating occurrences of battery faults among at least some of the physical batteries 304A, 304B, 304C, etc. For example, the battery fault data 314 may include fault logs indicating the time at which a battery fault occurred, as well as the type of battery fault that occurred. The battery fault data 314 may include data representative of faults inferred to have occurred based on other metrics (e.g., estimated battery state data 310, indicating internal state variables for a battery that are indicative of a fault occurring).

In the example of FIG. 3, training input 316 for training a battery fault prediction model 320 is generated based on the estimated battery state data 310 and the operation input 312. FIG. 3 furthermore shows ground truth output 318 generated based on the battery fault data 314. In some instances, training input 316 and the ground truth output 318 are temporally indexed, which can enable the battery fault prediction model 320 to learn temporal relationships between the occurrences of battery faults and various battery states and environmental/use factors.

FIG. 3 illustrates the training input 316 and the ground truth output 318 being utilized to train the battery fault prediction model 320 to generate battery fault prediction output (e.g., similar to fault prediction 224) in response to estimated battery state input and operation input. For instance, a system may iteratively utilize samples from the training input 316 to generate fault predictions via the battery fault prediction model 320 and calibrate parameters 322 of the battery fault prediction model 320 using the ground truth output 318 until a stop condition is satisfied. The stop condition can take on various forms, such as performance of a predetermined number of training iterations or epochs, achieving certain loss characteristics, etc.

After calibration of the parameters 322 through training using the training input 316 and the ground truth output 318, performance evaluation 324 may be performed on the battery fault prediction model 320 using validation data 326. The validation data 326 may comprise a subset of the set of training data 308 not used in the training input 316 or the ground truth output 318. The performance evaluation 324 may comprise evaluation of various model performance criteria, such as mean absolute error, mean squared error, root mean squared error, and/or others. In response to determining that the performance of the battery fault prediction model 320 (determined via the performance evaluation 324) satisfies one or more performance conditions (at decision block 328), the system may output a trained battery fault prediction model for deployment (as indicated by the “Yes” arrow extending from the decision block 328 toward action block 330). Conversely, in response to determining that the performance of the battery fault prediction model 320 fails to satisfy the performance condition(s) (at decision block 328), the system may continue training the model (as indicated by the “No” arrow extending from the decision block 328 toward action block 332).

### Example Method(s)

The following discussion now refers to a number of methods and method acts that may be performed in accordance with the present disclosure. Although the method acts are discussed in a certain order and illustrated in a flow chart as occurring in a particular order, no particular ordering is required unless specifically stated, or required because an act is dependent on another act being completed prior to the act being performed. One will appreciate that certain embodiments of the present disclosure may omit one or more of the acts described herein.

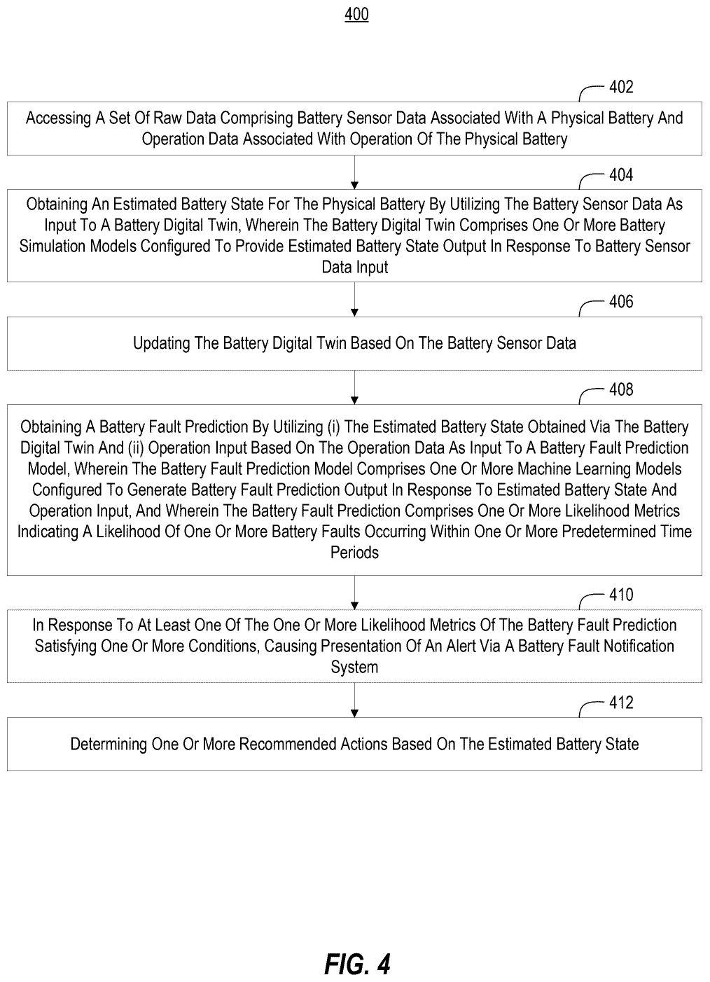

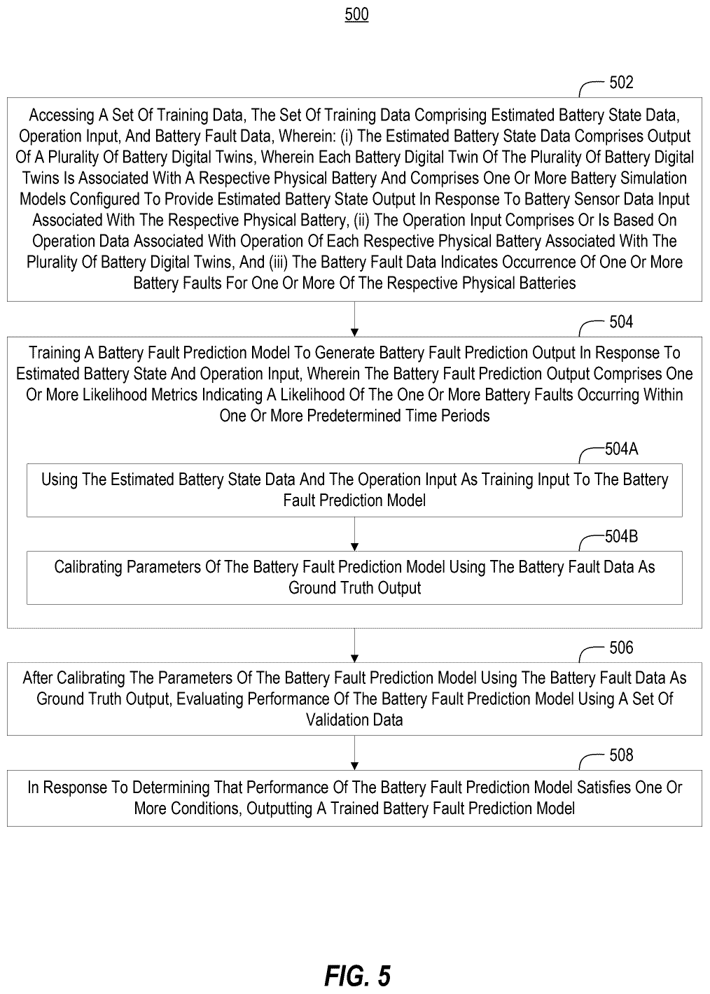

The acts described with reference to FIGS. 4 and 5 can be performed using one or more components of one or more systems 100 described hereinabove with reference to FIG. 1, such as processor(s) 102, storage 104, sensor(s) 110, I/O system(s) 114, communication system(s) 116, remote system(s) 118, etc.

FIGS. 4 and 5 illustrate example flow diagrams 400 and 500 depicting acts associated with facilitating battery fault prediction, in accordance with implementations of the disclosed subject matter.

Act 402 of flow diagram 400 of FIG. 4 includes accessing a set of raw data comprising battery sensor data associated with a physical battery and operation data associated with operation of the physical battery. In some instances, the battery sensor data comprises voltage data, current data, or temperature data for one or more components of the physical battery. In some implementations, the operation data comprises environment temperature data, location data, charge operation data, or discharge operation data. In some examples, the set of raw data is accessed via cloud infrastructure.

Act 404 of flow diagram 400 includes obtaining an estimated battery state for the physical battery by utilizing the battery sensor data as input to a battery digital twin, wherein the battery digital twin comprises one or more battery simulation models configured to provide estimated battery state output in response to battery sensor data input. In some instances, the estimated battery state comprises an estimation of capacity, state of charge, state of health, state of power, voltage state, current state, temperature state, internal resistance, charge transfer resistance, electrolyte state, charge/discharge cycles, depth of discharge, cell balance, pack balance, charge characteristics, or discharge characteristics. In some implementations, the one or more battery simulation models comprise or utilize one or more equivalent circuit models, one or more electrochemical models, one or more battery management system models, one or more thermal models, one or more aging models, or one or more physics-based models.

Act 406 of flow diagram 400 includes updating the battery digital twin based on the battery sensor data.

Act 408 of flow diagram 400 includes obtaining a battery fault prediction by utilizing (i) the estimated battery state obtained via the battery digital twin and (ii) operation input based on the operation data as input to a battery fault prediction model, wherein the battery fault prediction model comprises one or more machine learning models configured to generate battery fault prediction output in response to estimated battery state and operation input, and wherein the battery fault prediction comprises one or more likelihood metrics indicating a likelihood of one or more battery faults occurring within one or more predetermined time periods. In some examples, the one or more likelihood metrics comprise a likelihood score for each of the one or more battery faults. In some instances, the one or more battery faults comprise thermal runaway, rapid discharge, internal short circuit, cell imbalance, pack imbalance, rapid degradation, or battery failure. In some implementations, the operation input comprises the operation data or one or more operation states generated based on the operation data.

Act 410 of flow diagram 400 includes, in response to at least one of the one or more likelihood metrics of the battery fault prediction satisfying one or more conditions, causing presentation of an alert via a battery fault notification system. In some examples, the one or more conditions comprise one or more likelihood score ranges for each of the one or more battery faults.

Act 412 of flow diagram 400 includes determining one or more recommended actions based on the estimated battery state.

Act 502 of flow diagram 500 of FIG. 5 includes accessing a set of training data, the set of training data comprising estimated battery state data, operation input, and battery fault data, wherein: (i) the estimated battery state data comprises output of a plurality of battery digital twins, wherein each battery digital twin of the plurality of battery digital twins is associated with a respective physical battery and comprises one or more battery simulation models configured to provide estimated battery state output in response to battery sensor data input associated with the respective physical battery, (ii) the operation input comprises or is based on operation data associated with operation of each respective physical battery associated with the plurality of battery digital twins, and (iii) the battery fault data indicates occurrence of one or more battery faults for one or more of the respective physical batteries. In some instances, the battery sensor data input comprises voltage data, current data, or temperature data for one or more components of the respective physical battery. In some implementations, the operation data comprises environment temperature data, location data, charge operation data, or discharge operation data. In some examples, the estimated battery state data comprises, for each respective physical battery, an estimation of capacity, state of charge, state of health, state of power, voltage state, current state, temperature state, internal resistance, charge transfer resistance, electrolyte state, charge/discharge cycles, depth of discharge, cell balance, pack balance, charge characteristics, or discharge characteristics. In some instances, the one or more battery simulation models comprise or utilize one or more equivalent circuit models, one or more electrochemical models, one or more battery management system models, one or more thermal models, one or more aging models, or one or more physics-based models.

Act 504 of flow diagram 500 includes training a battery fault prediction model to generate battery fault prediction output in response to estimated battery state and operation input, wherein the battery fault prediction output comprises one or more likelihood metrics indicating a likelihood of the one or more battery faults occurring within one or more predetermined time periods. In some implementations, the one or more battery faults comprise thermal runaway, rapid discharge, internal short circuit, cell imbalance, pack imbalance, rapid degradation, or battery failure.

Act 504 can include various sub-acts. Sub-act 504A of act 504 includes using the estimated battery state data and the operation input as training input to the battery fault prediction model. Sub-act 504B of act 504 includes calibrating parameters of the battery fault prediction model using the battery fault data as ground truth output.

Act 506 of flow diagram 500 includes, after calibrating the parameters of the battery fault prediction model using the battery fault data as ground truth output, evaluating performance of the battery fault prediction model using a set of validation data.

Act 508 of flow diagram 500 includes, in response to determining that performance of the battery fault prediction model satisfies one or more conditions, outputting a trained battery fault prediction model.

### Experimental Results

The following discussion refers to experimental results. It shall be noted that the experiments giving rise to the following results were performed under specific conditions using a specific embodiment or embodiments; accordingly, neither these experiments nor their results shall be used to limit the scope of the disclosed subject matter.

In one experimental implementation, the disclosed battery fault prediction system was deployed in conjunction with a fleet of electric vehicles operating in mixed-use urban and suburban environments. Each vehicle was equipped with a telematics unit that transmitted real-time battery sensor data—including voltage, current, and temperature (e.g., corresponding to battery data 208)—at a sampling frequency of 0.1 Hz to a centralized cloud analytics engine. Complementary GPS telemetry and ambient environmental data (e.g., outside temperature, altitude, trip profile) are also captured to enrich the operational context (e.g., corresponding to operation data 210).

A digital twin (e.g., corresponding to battery digital twin 214) associated with each vehicle's battery pack was updated every 15 days, producing estimations of internal state variables such as state-of-health (SoH), state-of-charge (SoC), internal resistance, thermal state, and cell balancing efficiency (e.g., corresponding to estimated battery state(s) 216). These estimations, along with time-aligned environmental and usage features (e.g., corresponding to operation input 218), formed the input to a trained machine learning-based fault prediction model hosted in the cloud (e.g., corresponding to battery fault prediction model 222).

The fault prediction model was implemented as a hybrid ensemble of LSTM and gradient boosting classifiers. The fault prediction model was trained on over 200 million operating hours of fleet data and achieved an average F1 score of 0.93 for thermal and electrical fault classification tasks. The fault prediction modeled fault likelihood metrics (e.g., corresponding to likelihood metrics 226A, 226B, 226C) for several failure modes including thermal runaway, inter-cell imbalance, and progressive capacity degradation (e.g., corresponding to battery faults 228A. 228B, 228C).

In one scenario, the disclosed system detected a statistically significant rise in localized cell resistance combined with above-nominal temperature during consecutive charge cycles. Based on these features, the fault prediction model assigned a 0.82 probability to a cell imbalance fault manifesting within the next 72 hours (e.g., corresponding to time period 230A, 230B, 230C). This exceeded the system's alert threshold of 0.75, triggering an automatic notification on the fleet dashboard (e.g., corresponding to action block 234). The system concurrently recommended derating the peak charge current by 20% and scheduling a battery module rebalancing service (e.g., corresponding to action block 238). By way of comparison, the predictive alert generated by the disclosed system was issued approximately 48 hours earlier than a built-in BMS fault detection mechanism, which typically responds to absolute voltage or temperature limits. In-field deployment logs indicated that the total end-to-end latency of the prediction pipeline of the presently disclosed system—from data capture to cloud inference to dashboard notification—can be under 300 milliseconds, enabling near-real-time fault handling.

Comparative evaluation across 45 fault events showed that the disclosed system detected issues an average of 38 hours earlier than conventional BMS techniques, and reduced unplanned service interruptions by over 60% across a six-month evaluation period.

In another example, the disclosed system inferred an early-stage capacity fade condition in an electric vehicle exposed to repeated shallow depth-of-discharge cycles (e.g., 40%-60% SoC). The disclosed system detected deviations in charge efficiency, increased internal resistance trends, and reductions in modeled usable capacity. These indicators led to the system outputting a predicted likelihood of capacity degradation, enabling advisory alerts several days before range loss would manifest to users. A conventional BMS failed to detect any anomaly, as absolute voltage and temperature parameters remained within acceptable limits.

In yet another example, the disclosed system flagged a statistically significant divergence in voltage profiles among cells within a battery pack during successive fast-charging events at elevated ambient temperatures. The disclosed system attributed this to incipient cell imbalance conditions and issued an early alert based on rising fault likelihood metrics. A conventional BMS failed to generate a warning until the voltage differential between cells exceed a fixed threshold (e.g., 30 mV), at which point the opportunity for mitigation had significantly narrowed.

The table below provides comparative performance metrics between the disclosed machine learning-based battery fault prediction system and conventional threshold-based battery management systems.

| | ML-Based | Traditional BMS Threshold |
|---|---|---|
| Metric | Fault Prediction Model | Alerts |
| Detection Approach | Predictive | Reactive |
| | (based on trends and future risk) | (based on rule-based thresholds) |
| Average Lead Time Before Fault | 36-72 hours | 0-12 hours |
| Onset | (advance prediction) | (typically post-symptom) |
| Precision (True Positives/Alerts) | 91% | 68% |
| Recall (True Positives/Total Faults) | 88% | 55% |
| False Positive Rate | 6% | 24% |
| Detection of Gradual Failures | Yes (e.g., thermal drift, impedance rise) | Often missed until severe |
| Thermal Fault Detection F1 Score | 0.93 | 0.61 |
| Alert Latency (Data to Notification) | <300 ms | Variable; often delayed |
| Mitigation Guidance | Yes (automated recommendations) | No (manual intervention required) |

### Additional Details Related to the Disclosed Embodiments

Disclosed embodiments may comprise or utilize a special-purpose or general-purpose computer including computer hardware, as discussed in greater detail below. Disclosed embodiments also include physical and other computer-readable media for carrying or storing computer-executable instructions and/or data structures. Such computer-readable media can be any available media that can be accessed by a general-purpose or special-purpose computer system. Computer-readable media that store computer-executable instructions in the form of data are one or more “computer-readable recording media”, “physical computer storage media” or “hardware storage device(s).” Computer-readable media that merely carry computer-executable instructions without storing the computer-executable instructions are “transmission media.” Thus, by way of example and not limitation, the current embodiments can comprise at least two distinctly different kinds of computer-readable media: computer storage media and transmission media.

Computer storage media (aka “hardware storage device”) are computer-readable hardware storage devices, such as RAM, ROM, EEPROM, CD-ROM, solid state drives (“SSD”) that are based on RAM, Flash memory, phase-change memory (“PCM”), or other types of memory, or other optical disk storage, magnetic disk storage or other magnetic storage devices, or any other medium that can be used to store desired program code means in hardware in the form of computer-executable instructions, data, or data structures and that can be accessed by a general-purpose or special-purpose computer.

A “network” is defined as one or more data links that enable the transport of electronic data between computer systems and/or modules and/or other electronic devices. When information is transferred or provided over a network or another communications connection (either hardwired, wireless, or a combination of hardwired or wireless) to a computer, the computer properly views the connection as a transmission medium. Transmission media can include a network and/or data links that can be used to carry program code in the form of computer-executable instructions or data structures, and which can be accessed by a general-purpose or special-purpose computer. Combinations of the above are also included within the scope of computer-readable media.

Further, upon reaching various computer system components, program code means in the form of computer-executable instructions or data structures can be transferred automatically from transmission computer-readable media to physical computer-readable storage media (or vice versa). For example, computer-executable instructions or data structures received over a network or data link can be buffered in RAM within a network interface module (e.g., a “NIC”), and then eventually transferred to computer system RAM and/or to less volatile computer-readable physical storage media at a computer system. Thus, computer-readable physical storage media can be included in computer system components that also (or even primarily) utilize transmission media.

Computer-executable instructions comprise, for example, instructions and data which cause a general-purpose computer, special-purpose computer, or special-purpose processing device to perform a certain function or group of functions. The computer-executable instructions may be, for example, binaries, intermediate format instructions such as assembly language, or even source code. Although the subject matter has been described in language specific to structural features and/or methodological acts, it is to be understood that the subject matter defined in the appended claims is not necessarily limited to the described features or acts described above. Rather, the described features and acts are disclosed as example forms of implementing the claims.

Disclosed embodiments may comprise or utilize cloud computing. A cloud model can be composed of various characteristics (e.g., on-demand self-service, broad network access, resource pooling, rapid elasticity, measured service, etc.), service models (e.g., Software as a Service (“SaaS”), Platform as a Service (“PaaS”), Infrastructure as a Service (“IaaS”), and deployment models (e.g., private cloud, community cloud, public cloud, hybrid cloud, etc.).

Those skilled in the art will appreciate that the invention may be practiced in network computing environments with many types of computer system configurations, including, personal computers, desktop computers, laptop computers, message processors, hand-held devices, multi-processor systems, microprocessor-based or programmable consumer electronics, network PCs, minicomputers, mainframe computers, mobile telephones, PDAs, pagers, routers, switches, wearable devices, and the like. The invention may also be practiced in distributed system environments where multiple computer systems (e.g., local and remote systems), which are linked through a network (either by hardwired data links, wireless data links, or by a combination of hardwired and wireless data links), perform tasks. In a distributed system environment, program modules may be located in local and/or remote memory storage devices.

Alternatively, or in addition, the functionality described herein can be performed, at least in part, by one or more hardware logic components. For example, and without limitation, illustrative types of hardware logic components that can be used include Field-programmable Gate Arrays (FPGAs), Program-specific Integrated Circuits (ASICs), Application-specific Standard Products (ASSPs), System-on-a-chip systems (SOCs), Complex Programmable Logic Devices (CPLDs), central processing units (CPUs), graphics processing units (GPUs), and/or others.

As used herein, the terms “executable module,” “executable component,” “component,” “module,” or “engine” can refer to hardware processing units or to software objects, routines, or methods that may be executed on one or more computer systems. The different components, modules, engines, and services described herein may be implemented as objects or processors that execute on one or more computer systems (e.g., as separate threads).

One will also appreciate how any feature or operation disclosed herein may be combined with any one or combination of the other features and operations disclosed herein. Additionally, the content or feature in any one of the figures may be combined or used in connection with any content or feature used in any of the other figures. In this regard, the content disclosed in any one figure is not mutually exclusive and instead may be combinable with the content from any of the other figures.

As used herein, the term “about”, when used to modify a numerical value or range, refers to any value within 5%, 10%, 15%, 20%, or 25% of the numerical value modified by the term “about”.

The present invention may be embodied in other specific forms without departing from its spirit or characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is currently claimed is:

1. A system for facilitating battery fault prediction, the system comprising:
one or more processors; and
one or more computer-readable recording media that store instructions that are executable by the one or more processors to configure the system to:
access a set of raw data comprising battery sensor data associated with a physical battery and operation data associated with operation of the physical battery;
obtain an estimated battery state for the physical battery by utilizing the battery sensor data as input to a battery digital twin, wherein the battery digital twin comprises one or more battery simulation models configured to provide estimated battery state output in response to battery sensor data input;
obtain a battery fault prediction by utilizing (i) the estimated battery state obtained via the battery digital twin and (ii) operation input based on the operation data as input to a battery fault prediction model, wherein the battery fault prediction model comprises one or more machine learning models configured to generate battery fault prediction output in response to estimated battery state and operation input, and wherein the battery fault prediction comprises one or more likelihood metrics indicating a likelihood of one or more battery faults occurring within one or more predetermined time periods; and
in response to at least one of the one or more likelihood metrics of the battery fault prediction satisfying one or more conditions, cause presentation of an alert via a battery fault notification system.

2. The system of claim 1, wherein the battery sensor data comprises voltage data, current data, or temperature data for one or more components of the physical battery.

3. The system of claim 1, wherein the operation data comprises environment temperature data, location data, charge operation data, or discharge operation data.

4. The system of claim 1, wherein the set of raw data is accessed via cloud infrastructure.

5. The system of claim 1, wherein the estimated battery state comprises an estimation of capacity, state of charge, state of health, state of power, voltage state, current state, temperature state, internal resistance, charge transfer resistance, electrolyte state, charge/discharge cycles, depth of discharge, cell balance, pack balance, charge characteristics, or discharge characteristics.

6. The system of claim 1, wherein the one or more battery simulation models comprise or utilize one or more equivalent circuit models, one or more electrochemical models, one or more battery management system models, one or more thermal models, one or more aging models, one or more machine learning models, or one or more physics-based models.

7. The system of claim 1, wherein the instructions are executable to further configure the system to update the battery digital twin based on the battery sensor data.

8. The system of claim 1, wherein the one or more likelihood metrics comprise a likelihood score for each of the one or more battery faults.

9. The system of claim 8, wherein the one or more conditions comprise one or more likelihood score ranges for each of the one or more battery faults.

10. The system of claim 1, wherein the one or more battery faults comprise thermal runaway, rapid discharge, internal short circuit, cell imbalance, pack imbalance, rapid degradation, battery underperformance, or battery failure.

11. The system of claim 1, wherein the operation input comprises the operation data or one or more operation states generated based on the operation data.

12. The system of claim 1, wherein the instructions are executable by the one or more processors to further configure the system to determine one or more recommended actions based on the estimated battery state.

13. A system for facilitating battery fault prediction, the system comprising:
one or more processors; and
one or more computer-readable recording media that store instructions that are executable by the one or more processors to configure the system to:
access a set of training data, the set of training data comprising estimated battery state data, operation input, and battery fault data, wherein:
the estimated battery state data comprises output of a plurality of battery digital twins, wherein each battery digital twin of the plurality of battery digital twins is associated with a respective physical battery and comprises one or more battery simulation models configured to provide estimated battery state output in response to battery sensor data input associated with the respective physical battery,
the operation input comprises or is based on operation data associated with operation of each respective physical battery associated with the plurality of battery digital twins, and
the battery fault data indicates occurrence of one or more battery faults for one or more of the respective physical batteries; and
train a battery fault prediction model to generate battery fault prediction output in response to estimated battery state and operation input, wherein the battery fault prediction output comprises one or more likelihood metrics indicating a likelihood of the one or more battery faults occurring within one or more predetermined time periods, wherein training the battery fault prediction model comprises:
using the estimated battery state data and the operation input as training input to the battery fault prediction model; and
calibrating parameters of the battery fault prediction model using the battery fault data as ground truth output.

14. The system of claim 13, wherein the battery sensor data input comprises voltage data, current data, or temperature data for one or more components of the respective physical battery.

15. The system of claim 13, wherein the operation data comprises environment temperature data, location data, charge operation data, acceleration data, motor rpm data, or discharge operation data.

16. The system of claim 13, wherein the estimated battery state data comprises, for each respective physical battery, an estimation of capacity, state of charge, state of health, state of power, voltage state, current state, temperature state, internal resistance, charge transfer resistance, electrolyte state, charge/discharge cycles, depth of discharge, cell balance, pack balance, charge characteristics, or discharge characteristics.

17. The system of claim 13, wherein the one or more battery simulation models comprise or utilize one or more equivalent circuit models, one or more electrochemical models, one or more battery management system models, one or more thermal models, one or more aging models, or one or more physics-based models.

18. The system of claim 13, wherein the one or more battery faults comprise thermal runaway, rapid discharge, internal short circuit, cell imbalance, pack imbalance, rapid degradation, battery underperformance, or battery failure.

19. The system of claim 13, wherein the instructions are executable by the one or more processors to further configure the system to:
after calibrating the parameters of the battery fault prediction model using the battery fault data as ground truth output, evaluate performance of the battery fault prediction model using a set of validation data; and
in response to determining that performance of the battery fault prediction model satisfies one or more conditions, output a trained battery fault prediction model.

20. A method for facilitating battery fault prediction, comprising:
accessing a set of raw data comprising battery sensor data associated with a physical battery and operation data associated with operation of the physical battery;
obtaining an estimated battery state for the physical battery by utilizing the battery sensor data as input to a battery digital twin, wherein the battery digital twin comprises one or more battery simulation models configured to provide estimated battery state output in response to battery sensor data input;
obtaining a battery fault prediction by utilizing (i) the estimated battery state obtained via the battery digital twin and (ii) operation input based on the operation data as input to a battery fault prediction model, wherein the battery fault prediction model comprises one or more machine learning models configured to generate battery fault prediction output in response to estimated battery state and operation input, and wherein the battery fault prediction comprises one or more likelihood metrics indicating a likelihood of one or more battery faults occurring within one or more predetermined time periods; and
in response to at least one of the one or more likelihood metrics of the battery fault prediction satisfying one or more conditions, causing presentation of an alert via a battery fault notification system.
